(19) United States
(12) Patent Application Publication
(10) Pub. No.: US 2013/0053281 A1
(43) Pub. Date: Feb. 28, 2013

(54) FLUID SAMPLING DEVICE AND METHOD OF USE THEREOF

(71) Applicants: Arash Zarrine-Afsar, North York (CA); Christina Muller, Toronto (CA); Francis O. Talbot, Toronto (CA); Alexander Paarmann, Berlin (DE); R.J. Dwayne Miller, Port Credit (CA)

(72) Inventors: Arash Zarrine-Afsar, North York (CA); Christina Muller, Toronto (CA); Francis O. Talbot, Toronto (CA); Alexander Paarmann, Berlin (DE); R.J. Dwayne Miller, Port Credit (CA)

(21) Appl. No.: 13/576,928

(22) PCT Filed: Feb. 1, 2011
(86) PCT No.: PCT/CA2011/050058

§ 371 Date: Oct. 31, 2012

Related U.S. Application Data
(60) Provisional application No. 61/300,623, filed on Feb. 2, 2010.

(51) Int. Cl. C40B 60/14; B01L 3/00; G03F 7/20; C40B 50/14

(52) U.S. Cl. 506/30; 506/40; 422/547; 430/320

(57) ABSTRACT

A device is provided for the controlled sampling of fluid into a well formed within an upper surface, in which the well may be filled under dynamic wetting conditions by contacting a droplet on the upper surface with the top of the well. Wetting is supported by the increased hydrophilicity of the upper surface relative to that of the well side wall. The relative difference in hydrophilicity may be achieved by providing an upper surface with greater roughness than the side wall, effectively amplifying the hydrophilicity of the upper surface relative to that of the side wall. Wells are preferably formed in an unpolished surface of a siliconwafer, and can achieve a stable film with micron depth and an aspect ratio in excess of 100.

### CROSS-REFERENCE TO RELATED APPLICATION

This application claims priority to U.S. Provisional Application No. 61/300,623 titled “Fluidic Sampling Device and Method of Use Thereof” and filed on Feb. 2, 2010, the entire contents of which are incorporated herein by reference.

### FIELD OF THE INVENTION

The present invention relates to the preparation of liquid samples in wells for subsequent analysis. More particularly, the present invention also relates to characterization of liquids on microscale dimensions.

### BACKGROUND OF THE INVENTION

Analytical techniques such as microscopy, optical spectroscopy, and mass spectroscopy often require the preparation of a low volume and thin film sample for analysis due to the short absorption depth of the source. While this may be feasible with solid samples using precision methods, it can be a challenge with liquid samples. Unfortunately, the majority of the methods developed to facilitate the production of thin and stable liquid films require a relatively large volume of the liquid (e.g. microliters) to produce sufficient spreading, and hence these methods are not compatible with the applications which require ultra-small or low-volume (for example, picoliter), yet stable, liquid films for the analysis. This problem is compounded for applications that require open access to the sample during the analytic phase, including certain mass spectrometry methods. While thin liquid films can be readily produced in an enclosure, this approach is not compatible with applications such as mass spectrometry that require open access to the film.

Existing technology platforms for producing a thin spreading either require sizable setups (e.g. rotational spinning, enhanced laminar flow device, osmosis etc.) which are difficult to adapt to commercial analytical devices and require a large volume of analyte to produce the spreading, or use surfactants (or additives) to assist in the production of thin films by modulating the surface tension. Such additives may cause problems such as interfere with the analysis (e.g. by denaturing protein complexes of interest), and are not useful in many applications.

The electro-wetting method to produce thin films utilizes an external electric field to cause instability in the contact line and overcome the surface tension. However, to form micron length films by electro-wetting, a high electric field must be applied, resulting in the expulsion of small drops from the surface of the film (charge density becomes very large, especially near the contact line). This leads to substantial losses in the sample volume, making electro-wetting incompatible with microscale wetting with picoliter sample volumes. Furthermore, the applied external electric field across the solution may have an adverse effect on the sample chemistry (e.g. by promoting a dissociation of the protein complexes).

Consequently, there is a need for a sample-handling device and method that allows for the reproducible sampling of stable yet thin and low volume liquid samples.

### SUMMARY OF THE INVENTION

Embodiments of the present invention address the aforementioned need by providing sampling devices that allow for efficient, reproducible and selective wetting of wells. In a first aspect, the invention provides a device comprising a planar upper surface having a well defined therein, in which the hydrophilicity of the surface is greater than the hydrophilicity of the well's side wall, such that the well structure may be selectively wettable by a liquid on the surface when contacted with the top of the well. This embodiment enables the controlled wetting and capture of the liquid in wells having a wide range of aspect ratios (of width to depth), for example, exceeding 100. The well depth is preferably on the micron scale for producing stable yet thin liquid samples.

Accordingly, in a first aspect, there is provided a liquid sampling apparatus comprising a well formed within a substrate, the substrate comprising a hydrophilic top surface, wherein a hydrophilicity of the top surface exceeds a hydrophilicity of a side wall of the well, and wherein a hydrophilicity of the top surface is sufficient for dynamic wetting of the well. The contact angle of the top surface is preferably between approximately 50 and 70 degrees.

The hydrophilicity of the top surface and the hydrophilicity of the side wall may be selected such that a difference between a contact angle of the top surface and a contact angle of the side wall is sufficient for promotion of wetting of the well.

The top surface may comprise a surface roughness that exceeds a surface roughness of the side wall. The substrate may comprise a semiconductor wafer, and wherein the top surface comprises an unpolished surface of the wafer. The surface roughness may be on a micron scale, and the side wall may comprise surface roughness on a nanometer scale.

A bottom surface of the well is a hydrophilic surface, and wherein the bottom surface comprises surface roughness on a micron scale. An average surface roughness of the bottom surface may be approximately equal to a depth of the well, or an average surface roughness of the bottom surface may be approximately equal to an average depth of liquid that may be collected within the well. The surface roughness of the top surface may be substantially equal to a surface roughness of a bottom surface of the well.

The depth of the well may be on a micron scale or a nanometer scale.

A ratio of an average width of the well to an average depth of the well may exceed 10, or may exceed 100.

The top surface comprises an oxide coating layer when the substrate comprises silicon. The substrate may be transparent within at least a portion of one or more of the ultraviolet spectrum and the visible spectrum. The substrate may comprise silicon dioxide.

Dimensions of the well may be selected to capture a pre-selected average number of particles of a given particle size, where, the average number of particles may be unity.

A portion of the substrate beneath the well may be at least partially transparent to electromagnetic radiation, where the electromagnetic radiation may comprise x-rays.

The well may extend through a bottom side of the substrate.

The apparatus may further comprise one or more additional wells, wherein the wells are formed in an array.

In another aspect, there is provided a liquid sampling apparatus comprising a substrate having formed, on a surface thereof, a film comprising a nanometer scale thickness, and the film having an aperture formed therein; wherein the aperture and the surface of the substrate define a well, and wherein a hydrophilicity of a top surface of the film is sufficient for dynamic wetting of the well.

The film may comprise silicon nitride. A roughness of the top surface of the film may exceed a roughness of a side wall of the well. The substrate may be selected from the group consisting of silicon and silica.

The apparatus may further comprise one or more additional wells, wherein the wells are formed in an array.

In yet another aspect, there is provided a method of fabricating a liquid sampling apparatus comprising a microwell; the method comprising the steps of: providing a substrate comprising a hydrophilic top surface, the top surface comprising a surface roughness on a micron scale; applying a layer of photoresist onto the top surface; lithograhically exposing a region of the top surface, the region defining an aperture of the microwell; fabricating the microwell by reactive ion etching, the microwell comprising a bottom surface, wherein the bottom surface comprises a surface roughness approximately equal to or exceeding the surface roughness of the top surface; and removing remaining photoresist from the top surface.

The step of lithograhically exposing the region of the top surface may further comprise the step of photolithograhically exposing one or more additional regions of the top surface, wherein the step of fabricating the microwell comprises fabricating one or more additional microwells, the microwells defining an array on the substrate.

A thickness of the substrate beneath the microwell may be reduced by wet chemical etching prior to the step of fabricating the microwell. The substrate may comprises silicon, and the step of reducing the thickness of the substrate may comprise the steps of: forming a top layer of silicon nitride on a top of the substrate and a bottom layer of silicon nitride on a bottom layer of the substrate; removing a portion of the bottom layer by reactive ion etching, and defining an aperture; contacting the substrate with KOH and etching the substrate through the aperture, wherein the etching is performed to obtain a suitable substrate thickness.

In another aspect, there is provided a housing for providing external access to one or more wells of a liquid sampling apparatus, the liquid sampling apparatus provided according to any one of claims 1 to 28, the housing comprising: a support platform for receiving the liquid sampling apparatus; a reservoir for maintaining a vapor pressure within the housing; a slidable cover for enclosing the liquid sampling device and the reservoir within the housing, the cover further comprising an aperture for providing external access to one or more wells of the liquid sampling device when the liquid sampling device is enclosed within the housing; wherein the cover may be translated to position the aperture over the one or more wells while enclosing a remainder of the one or more wells and the reservoir.

The reservoir may comprise an adsorbent material. The reservoir may comprise a liquid that is substantially equivalent to a liquid contained in the one or more wells. The aperture may be larger than a distal portion of a droplet dispensing device.

In still another aspect, there is provided a method of sorting particles into wells of a liquid sampling apparatus, the method comprising the steps of: forming a droplet comprising one or more particles; providing a liquid sampling apparatus according to claim 24 or 29, wherein dimensions of the wells are selected to capture a selected average number of the particles per well; contacting at least a portion of the droplet with the top surface; and translating the droplet relative to the top surface to contact a given well of the array, wherein a portion of the droplet fills the given well. The average number of the particles may be selected to be unity.

The droplet may be translated past a distal wall of the given well, wherein a liquid film ruptures and liquid from the droplet is consequently captured by the given well. The step of translating the droplet may be performed by a process selected from the group consisting of wiping and brooming the droplet. The step of translating the droplet may be performed by a process selected from the group consisting of spin coating and shaking. The step of translating the droplet relative to the top surface may be repeated to contact at least one additional well of the array.

The particles may be selected from the group consisting of cells, crystals, casts, bacteria, viruses, biosensing functionalized particles, and semiconductor nanostructures, and a combination thereof.

The method may further comprise the steps of: providing a housing according to claim 34, and, prior to the step of contacting at least a portion of the droplet with the top surface, performing the following steps: enclosing the liquid sampling apparatus in the housing; and translating the cover to position the aperture over the given well.

The particles may comprise crystals, wherein a bottom portion of the given well is substantially transparent to x-rays; the method further comprising the step of performing x-ray crystallography on the particles. A hydrated state of the crystals may be maintained while performing x-ray crystallography on the particles.

In still another aspect, there is provided a method of controlling growth of protein crystals in wells of a liquid sampling apparatus, the method comprising the steps of: forming a droplet comprising a crystal growth solution; providing a liquid sampling apparatus according to claim 24 or 29, wherein dimensions of the wells are selected to capture a selected average number of the protein crystals per well; contacting at least a portion of the droplet with the top surface; and translating the droplet relative to the top surface to contact a given well of the array, wherein a portion of the droplet fills the given well.

The crystal growth solution may comprises a precipitant for forming the protein crystals. The method may further comprise the steps of: providing a housing according to claim 33, and, prior to the step of contacting at least a portion of the droplet with the top surface, performing the following steps: enclosing the liquid sampling apparatus in the housing; and dispensing a solution comprising a precipitant onto the reservoir.

Additional aspects of the invention further provide methods in which dynamically wettable wells may be employed for a number of analytical methods, including mass spectrometry, particle sorting, room temperature crystallography, photocrystallography, and electron beam analysis.

A further understanding of the functional and advantageous aspects of the invention can be realized by reference to the following detailed description and drawings.

### BRIEF DESCRIPTION OF THE DRAWINGS

The embodiments of the present invention are described with reference to the attached figures, wherein:

FIG. 1 illustrates a preferred embodiment of the invention comprising a wettable well for stable and reproducible fluidic capture.

FIG. 2 illustrates embodiments of the invention in which increased wettability is achieved by providing an upper surface having increased hydrophilicity relative to the well side wall.

FIG. 3 illustrates an embodiment of the invention in which surface roughness is utilized to control and increase hydrophilicity.

FIG. 4 illustrates the role of the side wall hydrophilicity in determining the meniscus shape and volume of liquid captured in a well, where (a) shows a well with smooth side walls (lower hydrophilicity and higher contact angle) and (b) shows a well with roughened side walls (higher hydrophilicity and lower contact angle).

FIG. 5 shows (a) a photograph of a silicon wafer with an array of wells, and (b) an array of wells where a collection of the wells have been filled through dynamic wetting.

FIG. 6 shows photographs in which wells formed within a fluidic chip are selectively wetted and filled with various liquids.

FIG. 7 shows confocal microscope images of a well filled with liquid.

FIG. 8 illustrates a fluidic chip holder incorporating a fluidic reservoir for humidity control and well hydration.

FIG. 9 shows an illustration of the water recoil phenomenon.

FIG. 10 illustrates an apparatus in which a thin liquid film is prepared in a well for applications in laser desorption involving water recoil, where the well is aligned with the inlet of a mass spectrometer device.

FIG. 11 provides images of the contact angle on various surfaces, including (a) fused silica with micron scale roughness, (b) fused silica with nanometer scale roughness, (c) fused silica with thin 100 nm nitride, (d) silicon with micron scale roughness, and (e) silicon with nanometer scale roughness.

FIG. 12 provides (a) an image of a microwell formed by the removal of a nitride layer, FIG. 12(b) is an optical microscopy image showing the wetting of wells by moving a large droplet of water (direction of movement is indicated by large arrow), showing the affinity of liquid for the wells. In FIG. 12(c), a confocal microscopy image is provided of one well of the array, where the well is wetted by a solution of rhodamine. The liquid meniscus is within the practical resolution of the microscope (less than 2.1 microns).

FIG. 13 shows photographs of particles sorted into an array of fluidic wells.

FIG. 14 shows a series of video frames illustrating the capture of particles into an array of wells from a large droplet with a receding meniscus.

FIG. 15 illustrates the dynamic wetting of wells for particle sorting, where (a) shows the selective capture of small beads from a collection of small and large beads into an array of wells, where the well dimensions are selected to exclude the large beads, and where (b), (c) and (d) show the capture of 2 micron diameter beads from a collection of both 2 and 8 micron diameter beads using an array of 4 micron diameter wells.

FIG. 16 provides images of an array of 4 micron diameter wells, where (a) shows an empty array, and (b) shows an array after capture of 2 micron beads.

### DETAILED DESCRIPTION OF THE INVENTION

Generally speaking, the systems described herein are directed to fluidic sampling wells having controlled hydrophilicity for dynamic wetting. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, the illustrated embodiments are directed to well arrays for capturing stable fluid aliquots from surface droplets.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

As used herein, the terms “about” and “approximately, when used in conjunction with ranges of dimensions of particles, compositions of mixtures or other physical properties or characteristics, is meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present invention.

As used herein, the coordinating conjunction “and/or” is meant to be a selection between a logical disjunction and a logical conjunction of the adjacent words, phrases, or clauses. Specifically, the phrase “X and/or Y” is meant to be interpreted as “one or both of X and Y” wherein X and Y are any word, phrase, or clause.

In a first embodiment, a device is provided comprising a planar surface having a well defined therein, in which the hydrophilicity of the surface is greater than the hydrophilicity of the well side wall, such that the well structure may be selectively wettable by liquid on the surface when the liquid is contacted with the top of the well. This embodiment enables the controlled wetting and capture of liquid in wells having a wide range of aspect ratios (of width to depth), for example, exceeding one hundred. The well depth is preferably on the micron scale for producing stable yet thin liquid samples.

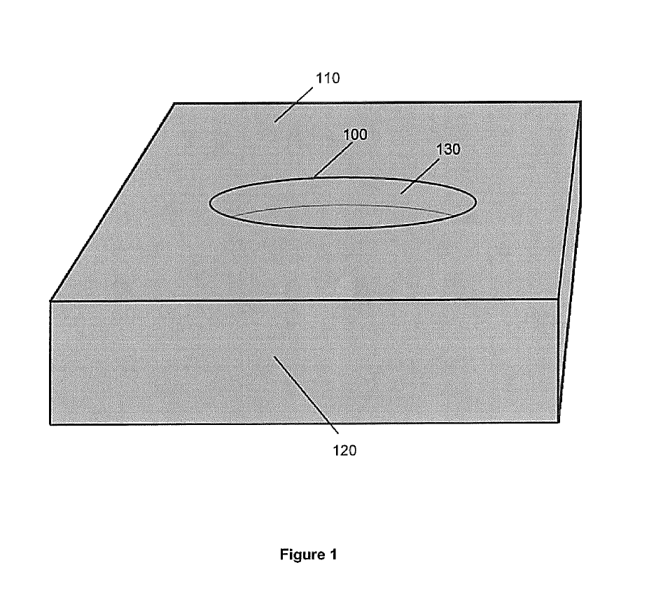

Accordingly, a first embodiment of the invention, as illustrated in FIG. 1, provides a liquid sample holder comprising a well 100 extending below a hydrophilic upper surface 110. In a non-limiting embodiment, the upper surface may comprise the surface of a substrate 120 in which the well is formed, as shown in the Figure. The side walls 130 of the well are also hydrophilic, but possess a hydrophilicity that is less than that of the upper surface. As discussed below, this decrease in hydrophilicity from the upper surface to the side wall of the well results in several benefits, including improved capture of liquid into the well. These benefits can be better understood by considering the roles of hydrophilicity and geometry when wetting a well from liquid on a surface.

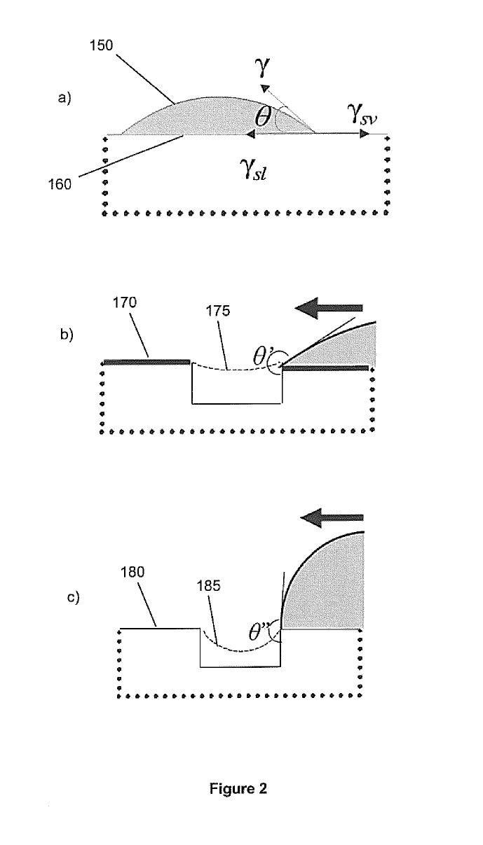

Referring now to FIG. 2(a), the equilibrium wetting properties of a drop of liquid 150 placed on a smooth surface 160, can be described by the Young equation below:

cos θ=(γₛᵥ−γₛₗ)/γ,

where θ is the equilibrium contact angle, γₛᵥ, γₛₗ and γ are interfacial solid-vapor, solid-liquid and liquid-vapor tensions, respectively. If the contact angle approaches zero, then a complete wetting of the surface will take place, resulting in a stable thin liquid film with an average thickness value of δ.

FIGS. 2(b) and 2(c) illustrate the operation of an embodiment of the invention in which the principle of dynamic wetting is employed to fill a well structure with liquid by the relative translation of a droplet along the upper surface towards the top of the well. While not intending to be bound by theory, the movement of the contact line (defined by the contact angle on the top surface) towards the top edge of the well structure is believed to promote the capture of liquid by the well.

In FIG. 2(b), the upper surface 170 of the substrate has a hydrophilicity that is larger than that of the well side walls. FIG. 2(c), by comparison, shows a well in which the hydrophilicity of the upper surface 180 is equal to that of the well side wall. Comparing the figures, a drop of liquid placed on the upper surface in FIG. 2(b) and contacted with the top of the well causes the change in the contact line (given by the angle θ′ between the contact angle θ, and the top edge of the well) to be greater than the corresponding θ″ angle in FIG. 2(c).

The relative hydrophilicity of the top surface of the substrate and that of the well side walls may be quantified by the difference in the liquid contact angle between the two surfaces. In an embodiment, in which the substrate is silicon with a top surface having a roughness on a micron scale, and where the well is formed with substantially smooth side walls, the contact angle of the top surface is typically in the range of approximately 50-60°, while the contact angle of the side walls is approximately 80-90°. Accordingly, the relative hydrophilicity between the side walls and the top surface may be manifested by a contact angle difference of approximately 20-40°. Generally speaking, the difference in the relative hydrophilicity of the side walls and the top surface is provided by a relative difference in contact angles that is sufficient to promote wetting.

As noted above, without wanting to be bound by theory, the increased angle shown in FIG. 2(b) is believed to enhance the wettability of the well. Furthermore, hydrophilic top surface facilitates thinning of liquid film after the wetting is complete and this allows efficient wetting of the well, and a larger volume of liquid to be captured inside the well.

As will be discussed below, this increased contact angle has been observed to produce a stable and reproducible meniscus, and has also been observed to support an increased volume of liquid trapped within the well. The increased volume contained within the well can be seen in FIG. 2(b) relative to that of FIG. 2(c) by the difference in the meniscus contours 175 and 185.

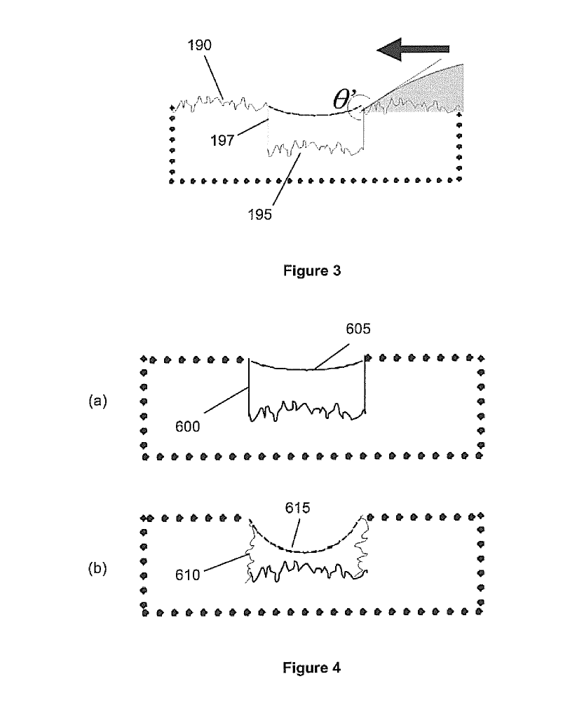

In a preferred embodiment shown in FIG. 3, the hydrophilicity of the upper surface is increased relative to that of the well side wall by incorporating roughness in the upper surface. A roughened surface is useful in amplifying the hydrophilicity of the surface, and therefore the roughness of the top surface produces an increased hydrophilicity of the upper layer. In a preferred embodiment, the top surface and the well side walls comprise a common material, and the roughness of the upper level therefore inherently increases the relative hydrophilicity of the upper layer.

Accordingly, surface roughness may be employed to control the hydrophilicity of the upper surface and the resulting contact angle between a liquid droplet on the surface that encounters the side wall of a well. In one preferred embodiment, the substrate comprises a silicon wafer (with a hydrophilic surface due to an intrinsic or overgrown oxide layer), and the hydrophilicity of the substrate surface relative to that of the well sidewall is preferably provided by the intrinsic roughness on the top surface of an unpolished side of the silicon wafer.

In the dynamic wetting process, the movement of the drop on the top edge of the well creates instability in the equilibrium contact line, and promotes the capture of liquid by the well structure. Once the liquid is captured inside the well, the roughness on the bottom wall 195 will further pin it to the well structure, such that once the moving drop has cleared the distal side wall the liquid film on the top surface ruptures resulting in wetting of the well. A lower contact angle on the top surface 190, due to roughness, will facilitate the film rupture on the distal side wall 197.

In another embodiment, the substrate comprises a hydrophilic substrate transparent within the ultraviolet and/or visible spectrum, such as silicon dioxide.

The increased relative hydrophilicity of the substrate surface may be achieved by roughness or by incorporating a surface layer with increased hydrophilicity on the substrate. The roughness may be provided by many different methods, including, but not limited to, cutting, sanding, and artificially-generated means such as lithography, embossing, and ion milling. Preferably, the roughness is within the Wenzel model such that the rough features amplify the hydrophilicity of the surface, as defined by both the RMS amplitude, as well as the spacing between the rough features.

In another embodiment, the bottom surface of the well comprises a hydrophilic surface to further assist in the spreading of liquid within the well when wetted. FIG. 3 shows a specific embodiment in which the hydrophilicity of both the upper surface and the well bottom are enhanced by surface roughness. As described below, surface roughness on the well bottom is advantageous for both improving the well wetting process and additionally for potentially capturing a larger volume of liquid, particularly when the well aspect ratio is high.

Some of the advantages of a roughened bottom well surface can be understood by considering the effect of the roughness on the wetting of the surface. If the drop is instead placed on a rough surface with a characteristic roughness scale α, such that α>>δ (where δ is the average film thickness), the liquid film will copy the shape of the substrate instead. More importantly, if the roughness scale α is approximately equal to, or on the order of, the average film thickness (α˜δ), a maximum deviation in film thickness Δδ from the corresponding equilibrium δ_{eq} value on the smooth surface is achieved. For example, the roughness of the bottom surface of the well may be controlled such that the average roughness is approximately equal to the well depth or approximately equal to an average depth of liquid that may be collected in the well.

This deviation can be exploited to maximize the volume of liquid captured inside a well possessing rough features on a scale satisfying the above condition. In this case, the mean thickness of the liquid film on rough surface δ will be larger than the corresponding thickness of film on a smooth surface. This consideration is consistent with the results presented in the examples below, where a well structure with roughness at its bottom surface is shown to wet better than its corresponding counterpart with a smooth bottom surface. An additional benefit of the increased mean thickness of the liquid film is a reduced evaporation rate.

FIG. 4 further illustrates the relative effect of smooth and roughened side walls on the meniscus and volume of liquid captured within a well. In FIG. 4(a), the well side wall 600 is smooth compared to the well bottom, resulting in a relatively low hydrophilicity that produces a high contact angle. The liquid meniscus 605 is therefore only moderately concave and the captured liquid volume is high. In FIG. 4(b), however, the roughened side wall results in relatively high hydrophilicity that yields a low contact angle. In this case, the corresponding meniscus is substantially more concave and the captured liquid volume is reduced.

In one embodiment of the invention, the well is formed within a substrate, and the roughness on the upper surface of the substrate is substantially duplicated on the bottom surface of a well, while providing side walls with less roughness. This may be achieved, for example, by methods including reactive ion etching (RIE), deep reactive ion etching (DRIE), PECVD and a variety of chemical etching methods, where the crystalline structure of the substrate allows for the etching proceed while preserving the roughness. If the rough unpolished side of a silicon wafer is subjected to reactive ion etching, the roughness on the top surface is substantially translated down or even enhanced as the etching nears completion, further augmented by the plasma bombardment such that the bottom surface of each well will contain at least approximately the same rough features that are present on the top surface of the substrate. The directional nature of plasma in isotropic RIE etching has been observed to produce a 90° angle between the top surface and the side wall.

One method utilizes the reproducibility and the precision associated with (deep) ion reactive etching and PECVD to ensure a highly reproducible well geometries. The side walls of the well are preferably substantially smooth in surface profile relative to the upper surface and the well bottom surface, which generates the desired change in relative hydrophilicity.

While a wide range of well sizes are compatible with the above embodiments of the invention, in a preferred embodiment, the well is a microwell having a depth on the micron scale, and the well aspect ratio, defined as the ratio of the average well diameter to the average well depth, is greater than unity. The well depth is preferably between approximately 1 μm and 100 μm, and the well aspect ratio, as defined above, is preferably between approximately 10 and approximately 100.

While the embodiments disclosed herein primarily involve cylindrical wells, it is to be understood that a wide variety of well shapes are intended to be included in the scope of the invention. Alternative shapes include, but are not limited to, oval, square, rectangular, and polygonal. In general, the liquid sampling device may comprise any shaped recess for containing a fluid relating to an upper surface in which a side-wall can be defined, including, but not limited to, wells, open channels, closed channels, capillaries, hemispheres, and other structures for containing fluid known in the art.

In another embodiment, the device comprises a plurality of wells forming an array. In a preferred embodiment, the device includes a two-dimensional array of microwells. While the spacing between wells in the array may take on a wide range of values, it is preferable that the inter-well spacing is on the same order of magnitude as the well average diameter.

In order to demonstrate the aforementioned benefits of certain embodiments of the invention, experiments were conducted using wells with and without roughness, as presented in the following non-limiting examples. The well structures were produced in a silicon wafer using reaction ion etching to form the wells beneath a top surface of the substrate. Due to the highly directional nature of the etching process, the features present on the top surface of the substrate are preserved during the course of etching. Therefore, if the rough unpolished side of a silicon wafer is subjected to reactive ion etching, the roughness on the top surface is substantially translated down or even enhanced as the etching nears completion, further augmented by the plasma bombardment such that the bottom surface of each well will contain at least approximately the same rough features that are present on the top surface of the substrate. The directional nature of plasma in isotropic RIE etching ensures a 90° angle between the top surface and the side wall.

The wells were fabricated as follows. The masks for photolithography were designed via L-Edit (Tanner Research, Monrovia, Calif., USA), and the corresponding chrome masks were produced using contact lithography (Fine-Line Imaging, Colorado Springs, Colo., USA). One mask comprised the wells with the radii of 100 μm as well as appropriate features to facilitate the backside alignment. The other mask comprised only the break marks to assist in detaching the chips after fabrication by scribing using a fine diamond tip, as well as a backside alignment feature complementary to the one present on the mask bearing the well structures.

Commercial silicon wafers (325±25 μm thick, p-type), single side polished, were purchased from WaferWorld (West Palm Beach, Fla., USA). Each wafer was first primed with a MicroPrime MP-P20 adhesion promoter at 3,500 rpm for 40 seconds using a spin coater and subsequently spin coated with a ˜2.5 μm thick layer of the MicroPosit S1818 resist (MicroPosit, Marlborough, Mass., USA) at 3,500 rpm for 40 seconds. Following baking at 90-115° C. for 90 seconds (on a hot plate), the coated wafers were first exposed (8 seconds) to soft UV on a commercial MA6 mask aligner (SussMicroTec, Munich, Germany) and subsequently developed by soaking in MicroPosit MF-321 developer (MicroPosit, Marlborough, Mass., USA) for 120 seconds (or until necessary for all of the exposed photoresist to completely come off). Prior to alignment and exposure, the backside of each wafer was also spin coated as above, and baked at 90° C., in an oven, for 1 hour. Break marks, on the backside, were aligned using the backside alignment features present on the photomasks.

Reactive F⁻ ion etching was performed with a Phantom etcher (Trion Technology, Clearwater, Fla., USA), operating with an SF₆/O₂/He mixture with a flow ratio of 22.5/1/1. The typical etch rate of silicon was characterized to be ˜2.7 μm per minute. The depths of the etched features were verified by contact profilomtery using a Tencor Alphastep 200 profilometer (KLA Tencor, Milpitas, Calif., USA) with a vertical resolution of 5 nm.

While the above example disclosed a method for producing a well having a higher hydrophilicity on the upper surface than the side wall using roughness, it is also possible to achieve such a structure using a deposition process whereby a hydrophilic coating is applied to the upper layer.

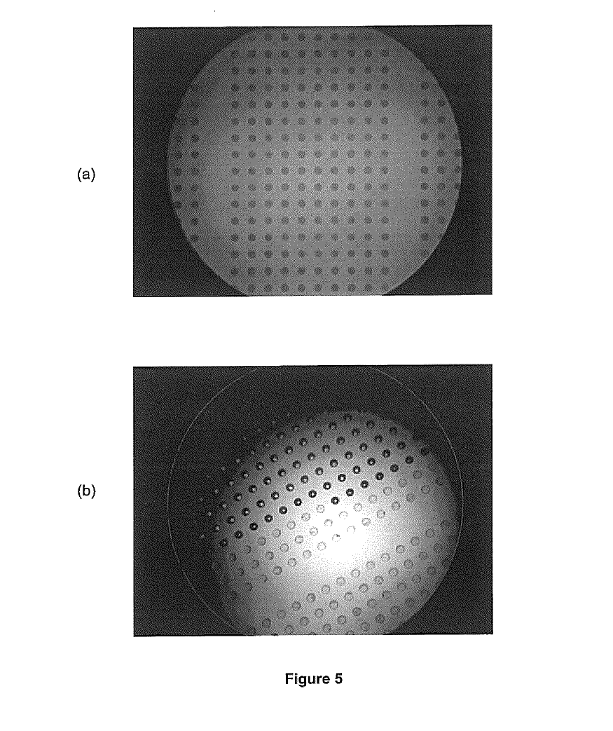

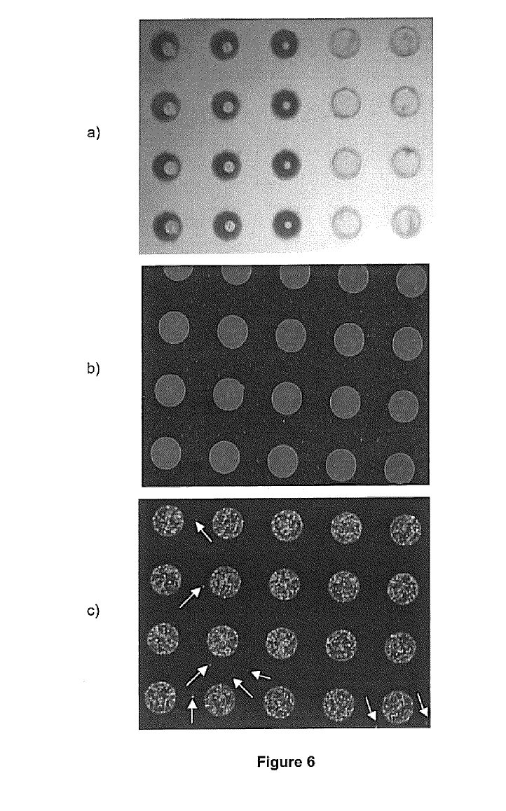

FIGS. 5(a) and 5(b) show photographs of an array of wells formed within a silicon substrate. In FIG. 5(b), a fraction of the wells have been selectively filled with water. FIG. 6(a) shows photographs of the fabricated wells, in which a series of wells are wetted by moving the chip against a stationary drop of water exiting a pipette. As seen in this figure, the spacing between the wells is not wetted. This demonstrates the effectiveness of the wells in terms of their wettab lity and ability to capture liquid from a surface droplet.

To further investigate the precision of the device, the same wells as in FIG. 1(a) were also wetted with a solution containing fluorescent quantum dots of high quantum yield, and the emission was evaluated using fluorescence intensity under an Upright fluorescence microscope (FIG. 1(b)). As shown in this figure, the emission intensities among the various wells are similar, suggesting that each well is filled with an approximately equal amount of quantum dot solution (also corroborated by quantifying the recorded intensities). This clearly demonstrates the quantitative and repeatable nature of the well wetting process according to embodiments of the invention. Moreover, no fluorescence signal was detected from the upper surface, suggesting that the spacing between the wells is not wetted.

To ensure that the wells were selectively wetted and captured material liquid from the surface with substantially no surface residual, an attempt was also made to wet the wells with a solution of fluorescent polystyrene beads with the diameter of 2.8 μm (on the order of the roughness scale present on the top surface). It was hypothesized that any residual wetting of the spacing between the wells will result in the beads being inevitably ‘captured’ by the rough features, readily detected by fluorescence microscopy.

As illustrated in FIG. 6(c), only 8 beads were detected as localized on the top surface (shown by the white arrows in the figure). This small quantity represents less than 0.1% of the total beads exclusively captured by the well structures. This result validates the use of devices according to various embodiments of the invention to selectively trap liquids containing particulate matter on the micron scale, such as biological cells.

Confocal microscopy was also used to image the liquid profile inside each well. In this experiment, wells were wetted with a rhodamine solution and a vertical depth scan (‘z-scan’) was performed to record a series of optical slices along the z-axis using two channels. One channel recorded the rhodamine fluorescence (to image the liquid profile in each well), and the other channel recorded the laser scatter at 543 nm (to image the well structure itself).

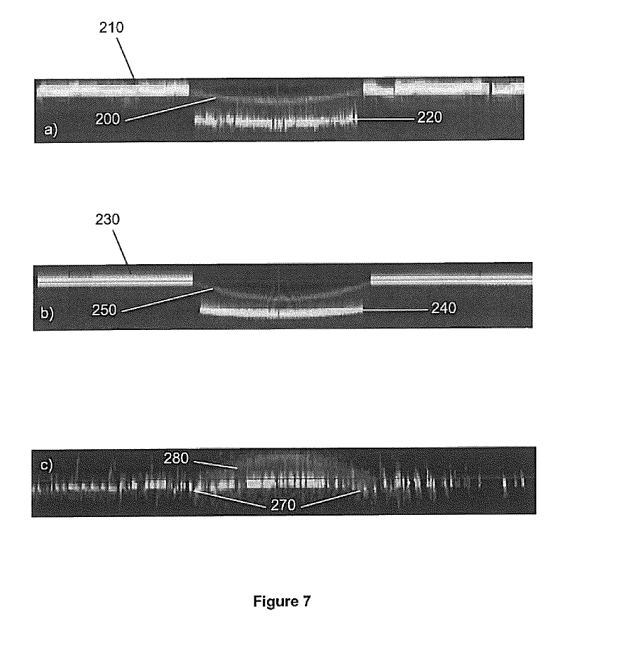

FIG. 7(a) shows the measured liquid profile 200 in a well structure with an aspect ratio of 10 fabricated into the unpolished side of a commercial silicon wafer. The upper surface 210 and bottom 220 well surface of this well is studded with rough features (on the order of 2-3 microns). In this image, the rough features manifest themselves as an elevated noise in the laser scatter signal used to image the well itself. As illustrated in this figure, the rhodamine solution selectively wetted the wells, as no residual fluorescence was detected on the top surface, consistent with the illustration presented in FIG. 3. Furthermore, the liquid profile in the well exhibited a slightly negative meniscus.

FIG. 7(b) shows measurements for a well structure with the same shape and aspect ratio as in FIG. 7(a), but fabrication with the polished surface 230 of a silicon wafer with the features on the nanometer scale. The bottom surface 240 of this well was smooth compared to the well in FIG. 7(a), only exhibiting features on the nanometer scale (the smoothness of the well structure, and the top surface, here is evident in a reduced noise in the laser scatter signal compared to the well structure shown in FIG. 7(a)). Through comparing the liquid meniscus profile 250 shown this figure, it is readily apparent that the well structure fabricated with roughness collected a significantly larger volume of liquid through dynamic wetting such that the volume of the collected liquid exceeds 90% of the total cylindrical volume of the well.

FIG. 7(c) illustrates the liquid profile in a well with an aspect ratio of 100 fabricated into the rough side 260 of a silicon wafer. Here, since the well is very shallow (the depth of the well is on the order of the random rough features of about 2-3 microns on the surface), the laser scatter signal fails to demonstrate a marked recession associated with the well structure as shown in the previous deeper wells. Nonetheless, the well side walls are apparent as the depressions 270 in the surface profile.

Strikingly, this shallow well possessing an aspect ratio of 100 is fully wetted by dynamic wetting, as evidenced by the meniscus profile 280 shown by the rhodamine signal. Moreover, no significant wetting of the top surface is detected, suggesting that the wetting observed in the well structure with the aspect ratio of 100 results from stable liquid capture by the well and does not stem from a non-specific spreading event. Unlike what was seen for deeper wells with the aspect ratio of 10 in FIG. 7(a) and (b), the water meniscus profile in this well (aspect ratio of 100) is convex and positive. Importantly, this demonstrates that high aspect ratio wells provided according to aspects of the invention are able to wet and confine liquid with a volume that is a large multiple of the inherent well volume. Accordingly, unlike prior art methods, aspects of the present invention utilizes a relative change in hydrophilicity between the upper surface and the well side wall to enhance wettability, thereby providing a general means to produce a thin spreading of a large spectrum of liquids.

It is to be understood that although the preceding embodiments disclose wells having a well bottom, bottomless well structures may also be formed, where the hydrophilicity of the top surface of the substrate in which the well is formed is higher than that of the well side wall such that the well is fully wettable through dynamic wetting.

Those skilled in the art will readily appreciate that the term “hydrophilic”, as used herein, is not intended to limit the scope of the invention to aqueous solutions, but is intended to address a general scope of liquids that interact with a surface through polar forces. For example, a non-limiting list of additional liquids compatible with the present invention include aqueous solutions containing particles (cells, viruses, specialized nano-fabricated particles, crystals), polar solvents, many organic solvents, body fluids such as blood and urine, cell culture media. Moreover, embodiments of the present invention do not require a multitude of photolithography rounds, which are essential components of other approaches presently used in the literature.

Furthermore, the embodiments disclosed herein demonstrate that by properly selecting the roughness scale of the substrate surface in accord with the aspect ratio of a microwell (i.e. by satisfying the α˜δ criterion) one is able to maximize wetting of a large variety of well designs with varying dimensions, aspect ratios and shapes. In addition, by taking advantage of the nanometer precision associated with reactive ion etching, the dynamic wetting strategy disclosed herein allows for substantially reproducible sampling of liquids in a high throughput fashion.

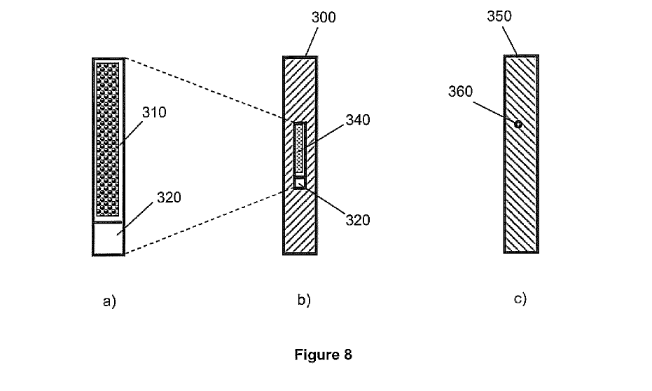

Aspects of the present invention also provide apparatus and methods for obtaining a stable thin spreading of a liquid sample within a well while allowing for access to the thin sample for downstream analysis. FIG. 8 shows a chip holder apparatus that can be employed to produce a stable thin spreading of liquid in wells according to the aforementioned embodiments of the invention. The chip holder may be formed in a variety of materials, and is preferably made of Teflon®.

The chip holder apparatus, shown in an open configuration in FIG. 8(b), comprises a supporting platform 300 into which a liquid sampling chip 310 having one or more wells is placed. FIG. 8(a) provides a detail view in which the liquid sampling chip can be seen. The liquid sampling chip can be any chip having wells defined therein, and preferably includes wells according to embodiments of the invention disclosed above. However, it is to be understood that the wells of the liquid sampling chip can have any geometry or surface chemistry, provided that they can contain a liquid. For example, liquid sampling wells may be fabricated according to the processes disclosed in US Patent Publication No. US2009/0093374, published on Apr. 9, 2009 entitled: METHOD OF ARRAYING CELLS AT SINGLE-CELL LEVEL INSIDE MICROFLUIDIC CHANNEL AND METHOD OF ANALYSING CELLS USING THE SAME, AND CELL ANALYSIS CHIP USED FOR CARRYING OUT THE SAME, which is herein incorporated by reference in its entirety. Furthermore, although the present embodiment is disclosed within the context of a plurality of wells, those skilled in the art will appreciate that the chip could house a single well.

Included in the platform is a saturating reservoir 320 that is provided to maintain vapor pressure within the chip holder when the holder is closed by lid 350. This design provides a saturating environment when the wells are enclosed within the chip holder, preventing substantial evaporation and maintaining a stable meniscus within the wells. The reservoir may be provided in any internal region of within the chip holder, and alternatively may be integrated within the chip itself for use within the chip holder. The reservoir may be filled with any liquid that can maintain an appropriate vapor pressure within the housing. Reservoir may also be in the form of an absorbent material such as sponge soaked with the liquid of interest. Preferably, the reservoir is filled with a liquid that is substantially the same as the particle-containing liquid. In several non-limiting examples, the liquid provided to the reservoir may be a sample liquid, a buffer, or a sample supernatant.

The chip holder is covered by a slidable lid 350, which includes aperture 360 for permitting access to the chip. Lid 360 has sufficient cross-sectional area to maintain coverage of all other wells within the chip when translating the lid relative to the liquid sampling chip. While the embodiment shown in FIG. 8 illustrates a chip holder with a two-dimensional array of wells, which would be accessed by translating lid 350 in a two-dimensional plane relative to liquid sampling chip 310, the liquid sampling chip may comprise a linear array of one or more wells that are accessed by translating lid 350 in one dimension.

In a preferred embodiment, aperture 350 is sufficiently large to deliver fluid for filling a single well. Fluid may be delivered to the well using a variety of means known in the art, such as direct pipetting, or dispensing using an automated system such as a syringe pump. In one embodiment, a well residing in the chip may be wetted by contacting a droplet of fluid with the chip surface, and translating the droplet relative to the chip so that it contacts the top of a well and fills the well according to a dynamic wetting process. Preferably, the dynamically filled well is provided according to the aforementioned embodiments, where the upper chip surface has a hydrophilicity exceeding that of the well side wall.

Wells may be dynamically welted by translating a droplet along the upper chip surface, for example, by translating one or both of the chip and the liquid source. In one non-limiting embodiment, a dynamically wettable well is filled by translating the aperture adjacent to a well, exposing the well and a portion of the upper surface in the vicinity of the well, contacting at least a portion of a droplet with the upper surface, and translating the droplet relative to the upper surface to contact the top of the well. The contact of the droplet with the top of the well transfers at least a portion of the droplet volume into the well. The liquid drop is the translated past the distal wall of the well structure where it contacts and wets the hydrophilic top surface again. This wetting facilitates liquid film rupture and promotes complete capture of liquid by the well structure. Translation of the lid, chip, and/or dispensing device may be achieved using motorized translation stages and devices known in the art, such as linear translation stages driven by linear motors or rotary stages in conjunction with an array design compatible with radial motion of the well array. Note that a substantially hydrophilic side wall results in pronounced concave meniscus, and reduces the volume of the liquid capture and hence lowers the efficiency of the device, as can be seen in FIG. 4 (b).

In one embodiment, the droplet is a partial droplet formed at an aperture of a liquid dispensing device, such as a hemisphere, which may be contacted with the upper surface and removed from the upper surface after filling a well without wetting the upper surface. This can be achieved by selecting a liquid dispensing device that supports droplet adhesion relative to the upper surface, such as a standard pipette tip.

After having filled a single well, additional wells may be filled with the residual fluid within the droplet by translating the chip relative to both the aperture 360 and the liquid dispensing device, thereby moving the droplet along the upper chip surface. An additional well may subsequently be filled by contacting the droplet with the top of the additional well and dynamically filling the additional well.

In a preferred embodiment, the liquid device may comprise a capillary filled with a fluid to be dispensed into one or more wells. For example, in one non-limiting embodiment, the capillary may form a component of a separation system, such as, but not limited to, a capillary electrophoresis system or a liquid chromatography system, where the serial dispensing of liquid into an array of wells enables a mapping of separated components within the capillary into an array of wells. With a known flow rate of dispensing into the wells, measurements from a given well can be correlated with a longitudinally separated segment of the capillary. In another embodiment, the capillary may reside within a sampling device such as a fingerstick blood sampling device, and the dispensing of blood within the capillary into the array of wells may be used to generate a precise spatial array of aliquots for subsequent analysis. The capillary may comprise a wide range of capillaries known in the art, such a fused silica capillary.

A well residing on a chip may be filled from the capillary as follows. A pressure gradient is applied to the capillary and at least a partial droplet is contacted with the upper chip surface. As described above, a well may then be dynamically filled by translating the droplet along the upper surface until it contacts the top of a well. Preferably, multiple wells in an array of wells are filled according to the aforementioned method whereby the chip is subsequently translated relative to both the aperture and the capillary, enabling the droplet to be translated and contacted with additional wells. As noted above, this enables the aliquoting of liquid in a capillary into a two-dimensional array of wells.

In another preferred embodiment, a chip filled and housed within a chip holder may be stored and/or processed (for example, frozen or thermally incubated) and subsequently utilized in an analytical process involving the serial analysis of wells. This subsequent analytic step is preferably achieved by providing access to pre-filled wells on a well-by-well basis via the translation of lid 350, where aperture 360 may be selectively translated to provide access to a single well. In a preferred embodiment, such a method is used to provide subsequent access to an analysis system, as further described in the non-limiting applications provided below.

In the above embodiments in which a liquid dispensing device (such as a pipette tip, pump and capillary) is employed to fill the wells via droplet contact and translation, it is to be understood that the liquid dispensing device is to be configured such that the surface adhesion force between the capillary tip and the drop of liquid exiting the capillary exceeds the adhesion force between the drop of liquid and the surface of the well array. This may be achieved by methods known to those skilled in the art, such as applying a coating to the surface of the liquid dispensing device aperture in order to control the surface tension and contact angle. An exemplary coating method is coating with a hydrophilic material such as poly lysine is an example.

### Sample Preparation for Mass Spectroscopy with Soft Ablative Laser Desorption

In this section, additional embodiments are provided in which aspects of the invention are advantageously employed for the preparation of samples for subsequent analysis by mass spectrometry (MS). In the realm of bio-analytical chemistry, in addition to a lower limit of detection often an accurate quantification of the molecule of interest is also highly desirable. While ultra-sensitive MS devices have been developed to make near single molecule detection of analytes possible, conventional MS ionization techniques, such as electrospray ionization and matrix-assisted laser desorption and ionization (MALDI), in which desorption and ionization are coupled together in a single process, inherently suffer from poor quantitative capabilities.

To improve the quantitative capabilities of MS, an inventive system and method has been disclosed by inventors of the present invention in a co-pending Patent Cooperation Treaty Application titled “Soft Ablative Desorption Method and System”, filed Feb. 2, 2010, with International Application Number PCT/CA2010/000136, which is incorporated by reference herein in its entirety. The novel approach capitalizes on the fact that selective laser pulses tuned to vibrational absorption of a sample can drive the soft ablation with great efficiency and repeatability, thereby enabling sensitive and quantitative mass analysis. Furthermore, post-ablation ionization may be achieved, for example, by the means of either corona-discharge ionization, or using photoionization by a UV and/or VUV laser pulses focused on the ablation plume.

The most notable advantage of adapting a MS-based technology for diagnostic applications, besides its high sensitivity, is the versatility of MS in analyzing a wide range of molecular masses, encompassing small molecules (e.g. as in urinalysis, drug metabolics etc) to large protein molecules (e.g. as in HIV Ab testing, blood biochemistry etc), or protein complexes (e.g. aggregates causing neurodegenerative diseases), which can be ablated substantially intact.

Since blood, urine and other body fluids which are routinely examined in diagnostic testing are primarily constituted of water, the inventive method, henceforth referred to as soft ablative laser desorption, is well-suited to the analysis of biological material, where it provides the combined advantages of MS sensitivity and quantitative analysis.

The ablative mechanism at the foundation of the method involves the rapid deposition of energy from an incident optical beam into vibrational excitations of a component of a sample, in which the energy is absorbed on a timescale that is faster than the timescale over which energy is lost beyond the irradiated zone to thermal diffusion and acoustic expansion. As a result, the energy is rapidly transferred into translation degrees of freedom of the absorbing component, leading to a superheat state that drives soft ablation in a direction perpendicular to the sample surface. A key benefit of this approach is that due to the rapid timescales involved, molecules of interest in the sample are desorbed substantially intact and uncharged with high efficiency.

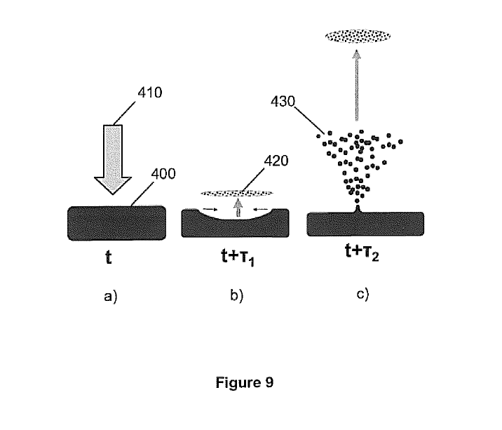

As described in the co-pending application, the irradiation of a liquid sample having a thickness greater than the absorption depth of the incident optical beam can lead to recoil effects, in which nano-droplets are ejected along with the primary ablation plume. This phenomena is illustrated in FIG. 9, where in step (a), a liquid sample 400 is shown irradiated by an incident optical beam 410. In step (b), ablative desorption produces an ablation plume 420 comprising a portion of the sample. As a result of this non-linear temperature profile, the expansion of ablation plume in all direction causes a void volume to be created in the bulk liquid, dramatically reducing the speed of ablation. Subsequently, in step (c), this void volume is ‘filled’ by the turbulence caused in the bulk liquid, creating tiny water droplets 430 referred to as ‘recoil water’, resulting in a substantial loss of the sample volume during the course of the analysis. This sample loss becomes an important problem in the applications which use ultra-small amounts of analytes.

In addition, to maximize collection of the molecular beam in a preferred embodiment described in the co-pending application, the collimated beam produced in a preferred geometry is aligned with the ion optics inside a MS device. Therefore, the well should be placed parallel to the MS entrance and in this preferred geometry recoil water droplet will enter the MS device, and this is not ideal. It is therefore beneficial to avoid such effects by preparing a liquid sample in a well in which the thickness of the sample is of the same order as the absorption depth of the optical beam. This enables to considerably reduce the amount of sample required for the analysis. This is especially challenging for water samples, where the absorption depth of infrared light by vibrational states is limited to only a few microns, and where losses due to evaporation can be problematic.

Therefore, a device comprising a sample well according to the aforementioned embodiments of the invention provides a suitable liquid sample holder for use with the soft ablative desorption method. By using such a well to achieve thin spreading of the liquid sample, the absorption profile of water matches the well depth, and as a result of this overlap, the thin layer is completely ablated without substantial recoil and sample loss. In a preferred embodiment, a well is provided having a depth approximately equal to the absorption depth of the soft ablative desorption optical beam in the sample liquid. As described above, such a well preferably is formed below an upper surface having a hydrophilicity greater than the well side wall to enable wetting of the well by liquid contacting the top of the well. More preferably, the well bottom also comprises a hydrophilic surface to enable the spreading of liquid across the full width of the well, thereby obtaining a thin spreading of the sample that is suitable for soft ablative desorption and subsequent analysis. Preferably, for aqueous samples, the well depth is on the micron scale, preferably with a depth of 1-2 microns, and well width is on the order of 100-200 microns. In another embodiment, the well bottom surface may comprise a hydrophilic surface having roughness on a micron scale, thereby allowing for the stable capture of a high aspect ratio and low volume liquid sample.

Preferably, the well material is compatible with the human body fluid chemistry, can selectively wet and confine small (for example, picoliter) volumes of aqueous solutions, and allows for an efficient ablation of the confined volume. Additionally, the device is preferably be cost-effective to produce using current available technology such as material processing, lithography, etching, and casting of polymers. In one embodiment the device may be reusable, and is preferably configured to be readily cleanable and/or sterilizable. The well material is also preferably compatible with routine point-of-care sampling methods, such as fingerstick capillary blood sampling devices.

Those skilled in the art will readily appreciate that these requirements are met by the aforementioned embodiments of the invention, particularly microwells formed in silicon and silicon dioxide, fused silica, having hydrophilic amplifying roughness on both the upper surface and the well bottom.

In a preferred embodiment, the well is formed in a substrate that is transparent to the soft ablative desorption source beam, thereby enabling the beam to be delivered through the substrate where it is absorbed by the sample.

As disclosed in co-pending PCT application PCT/CA2010/000136, the chip holder embodiment described above is particularly well suited to embodiments involving mass analysis, where the aperture may be used both for well wetting, and as an aperture through which the ablated plume may emerge. In one embodiment, the soft ablative desorption optical beam may be delivered through the aperture, where it is absorbed by a well aligned with the aperture. Preferably, the well substrate and the supporting platform of the chip holder is also transparent to the optical beam, and as a result, the optical beam may be delivered through the back of the chip holder and through the chip.

In particular, well structures produced in fused silica (highly transparent to light from the ultraviolet until the infrared regions of the electromagnetic spectrum provide opportunity for backside ablation, and ionization in a collinear or near collinear fashion with the collection optics of MS device. This embodiment may be employed in applications involving laser desorption MS where the thickness of the liquid film to be desorbed must be smaller than the absorption depth of the laser pulse. As described above, desorption of a liquid layer with thickness greater than absorption depth of the laser pulse results in massive recoil of liquid droplets which leads to loss of sample, and possibly large droplets entering the MS device. In applications where the pulse energy of the desorption laser necessitates that a liquid film on the order of 1-2 micron be used, similar approach.

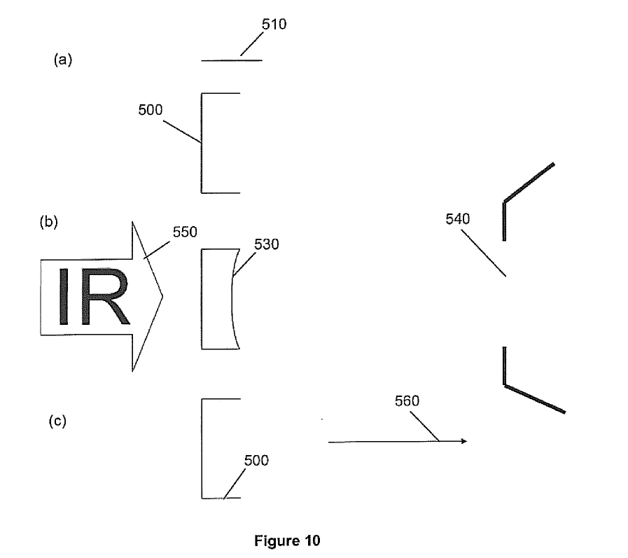

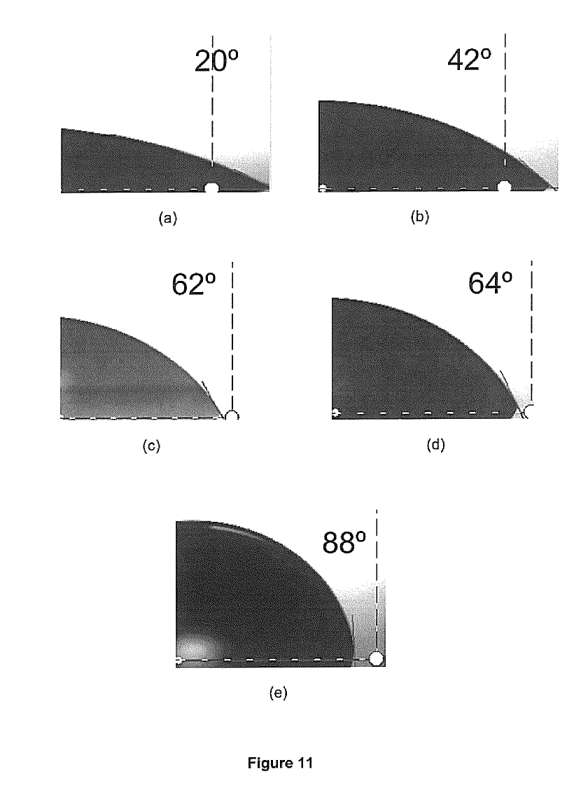

This geometry maximizes the ion capture and increases the sensitivity of the technique, and is illustrated in FIG. 10. In FIG. 10(a), well 500 is shown (substrate not shown) having a depth 510 less than an absorption depth of the desorption beam. FIG. 10(b) shows the filled well 530 aligned with the inlet 540 of a mass spectrometer. Incident desorption beam is 550 is absorbed by the liquid within well 530, and as shown in FIG. 10(c), the absorption of beam 550 causes the ejection 560 of liquid from well 500 due to water recoil.

Fused silica is transparent throughout the entire visible spectrum reaching far into the near infrared and partly into the ultraviolet regions, and allows the desorption radiation to be incident on the substrate from the backside such that the trajectory of the desorbed (and subsequently ionized) material is aligned with the collection optics of the MS device.

However, as shown in FIG. 11(a), fused silica with roughness on the micron scale possesses an intrinsic contact angle of 20 degrees for water. Polished fused silica with roughness on the nanometer scale also possesses a contact angle of 30-40 degrees (FIG. 11(b)), falling outside the desired range for dynamic wetting of approximately 50-70 degrees. Therefore, to adjust the contact angle to fall within the desired limit, a very thin (100 nm) layer of silicon nitride was deposited on smooth fused silica, which increased the contact angle to ˜60° (FIG. 11(c)). Furthermore, it is noted that silicon nitride deposition creates intrinsic roughness (hence hydrophilicity) on the top surface that will not be present on the side wall (the side wall roughness is substantially eliminated through the RIE process). Also provided in FIG. 11(d) and (e) are images of the contact angle of water on silicon with microscale and nanoscale roughness, respectively.

Accordingly, in one embodiment, a well having a depth on the nanometer scale is formed by depositing a layer of silicon nitride having a nanometer thickness onto a fused silica substrate, and removing a portion of the silicon nitride layer to define a well. The silicon nitride layer is deposited by non-limiting methods of Chemical Vapor Deposition (CVD), Plasma Enhanced Chemical Vapor Deposition (PECVD) or Low Pressure Chemical Vapor Deposition (LPCVD). Well structure patterns are introduced by lithography, and the wells are formed in the nitride layer by etching methods such as but not limited to Reactive Ion Etching (RIE).

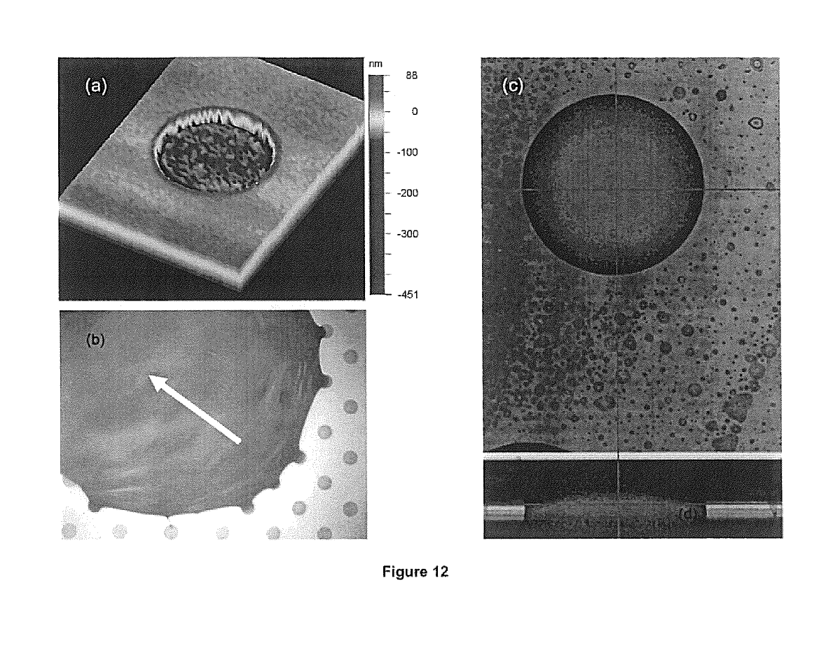

FIG. 12 provides images of an array of wells having a depth of approximately 100 nm and a diameter of about 200 microns, where the wells are formed in a fused silica substrate. In FIG. 12(a), a non-contact interferometry image is shown illustrating the smooth profile of the silicon nitride top layer and the steep nanoscale side walls of the well. FIG. 12(b) is an optical microscopy image showing the wetting of wells by moving a large droplet of water (direction of movement is indicated by large arrow), showing the affinity of liquid for the wells. In FIG. 12(c), a confocal microscopy image is provided of one well of the array, where the well is wetted by a solution of rhodamine. The liquid meniscus is within the practical resolution of the microscope (less than 2.1 microns).

In a related embodiment, aspects of the invention may be adapted for use as sampling devices for ultrafast probing of liquids on the molecular scale. Recently, the development of ultra-fast femtosecond lasers has made it possible to investigate real-time structural changes at atomic level, as they occur. To make a molecular movie of such changes, a thin nm-thick free standing film of a solid is subjected to an intense femtosecond laser pulse for superheating, and the structural changes are subsequently investigate by obtaining the diffraction data. Despite the advances made in femtosecond analyses of solids, the ultra-fast probing of liquids requires concentrate collimated molecular beams, and has proven nontrivial.

An ideal embodiment to produce collimated molecular beams utilizes a laser-induced ablation of liquids into vacuum, where a highly collimated ablation plume is produced. A complete characterization of liquids by ultra-fast electron diffraction requires that a large number of molecules be diffracted, one molecule at a time. A limitation of the current ablation methods which use the bulk liquid is the interference of the recoil water cluster, described above. Therefore, an ideal device to produce molecular beams suitable for ultra-fast characterization of liquids should suppress the water recoil.

Accordingly, as described above in association with the soft ablative desorption method, in an embodiment of the invention, the liquid sampling devices forming embodiments of the invention may be used as a sampling well for the efficient ablation of liquids with reduced water recoil studies involving the ultrafast probing of liquids on the molecular scale and the generation of collimated molecular beams.

### Sorting of Particles into Well Array

In a preferred embodiment, an array of wells is employed for the sorting of particles on a liquid sampling chip. A droplet containing particles is contacted with the upper surface, and the droplet is translated along the surface and made to contact one or more wells. The contact of the droplet with the top of the well causes the well to be wet due to an induced instability in the liquid contact line facilitated by the hydrophilicity contrast between the well side wall relative to the upper surface, as described in the above embodiments of the invention. The resulting fluid volume contained in a well upon removal of the droplet from contact with the top of the well may contain one or more particles, and the dynamic wetting of the well alone and not the upper surface of the liquid sampling chip results in the sorting of particles into the wells in fluid aliquots.

While US Patent Publication 2009/0093374, filed by Suh et al., discloses the use of liquid evaporation (i.e. receding water meniscus) to sort particles into wells for the purpose of further analytic studies, the present embodiment utilizes optimized dynamic wetting and accordingly allows for particle sorting in the absence of evaporation (i.e. under saturating environment). Accordingly, the devices and methods taught by Suh are not suitable for sorting particles whose quality (or the quality of the analytic data obtained from them) can be affected due to liquid evaporation (such as protein crystals that are kept in near saturated solutions of salts).

In this context, the word “particle” is intended to represent a wide variety of different insoluble species that may be provided within a liquid, including, but not limited to, cells, crystals, casts, bacteria, viruses, biosensing functionalized particles, and semiconductor nanostructures.

The probability of sorting a particle into a single well can be controlled by varying the density of particles within the fluid droplet. For example, a dilute droplet having a very low particle density (e.g. <<1 particle per well volume) will have a low probability of depositing a particle into a given well, while a high particle density (e.g. ˜1 particle per well volume) will have a high probability of depositing a particle into a given well.

In a preferred embodiment, the well volume is selected to accommodate, on average, a single particle per well. This condition typically results in particles sorted to deposit either one or no particles per well, which is desirable for a wide range of applications including, but not limited to, cell studies, crystal growth, and particle analysis.

In a preferred embodiment, the well bottom surface may be coated (for example, dried or lyophilized) with a substance favorable for the subsequent storage, growth, conditioning and/or analysis of the particle. For example, in the case of cell sorting, the well bottom may be coated with specific receptors for adhering to a biological cell, labeled receptors, lysis chemicals, reagents for altering the state of a cell, and/or cellular growth media.

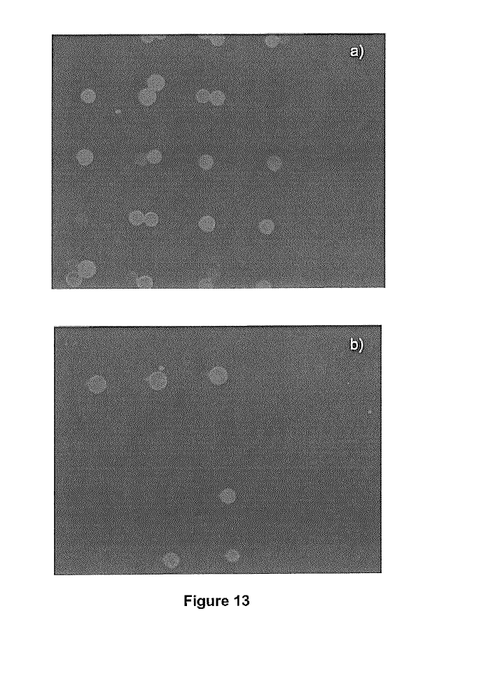

To demonstrate this embodiment experimentally, wells with smooth side walls were etched into the unpolished surface of a silicon wafer, according to a preceding embodiment of the invention. The wells had a diameter of 200 microns, and a depth of 40 microns. FIG. 13 shows the sorting of spherical beads into wells, where the bead diameter was 100 microns (i.e. half the well diameter).

As shown in FIG. 13(a), in a first dilution comprising a moderate bead concentration, all wells were filled with at least one bead, and several wells were filled with two beads. When the dilution was decreased by a factor of 2, many wells did not contain a bead, and bead-containing wells captured only a single bead. Accordingly, dilution may serves as a control means to vary the intra-well particle concentration and occupation probability.

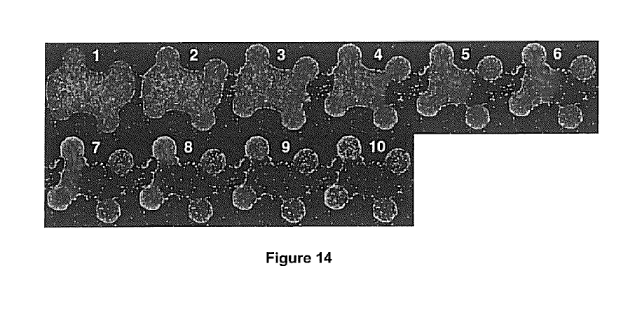

In a related experiment, a large fluid droplet spatially extending over multiple wells was placed on the upper surface of the well array (covering several wells). The droplet contained a high volume percentage of particles, and the average particle size was significantly less than the well diameter. The droplet was then withdrawn by a pipette tip, and the wells were filled with liquid by the receding droplet meniscus. As shown in the video frame sequence provided in FIG. 14, as the droplet was extracted, the particles were substantially captured by the wells. Accordingly, in a related embodiment, the capture of particles into a well may be achieved by contacting a droplet with the top of a well, and allowing the droplet to evaporate.

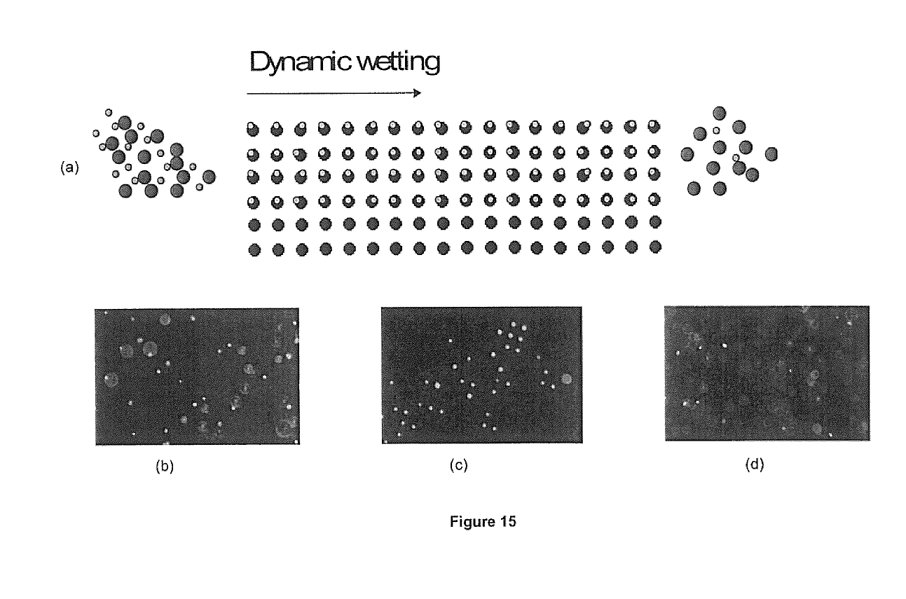

The sorting of beads into wells of an array is further illustrated in FIG. 15. In FIG. 15 (a), the selective capture of small beads from a collection of small and large beads into an array of wells is shown. In the illustration, the well dimensions are selected to exclude the large beads. Figures (b)-(d) show images of a well array on which the above method was demonstrated. The array comprises wells having a diameter of 4 microns. In part (a), both 2 and 8 micron diameter beads are provided onto the array. As the array is selectively wetted, only the 2 micron beads are captured in the wells, as shown in FIG. 15(b). In FIG. 15(c), the residual 8 micron beads that were not captured by the wells are shown.

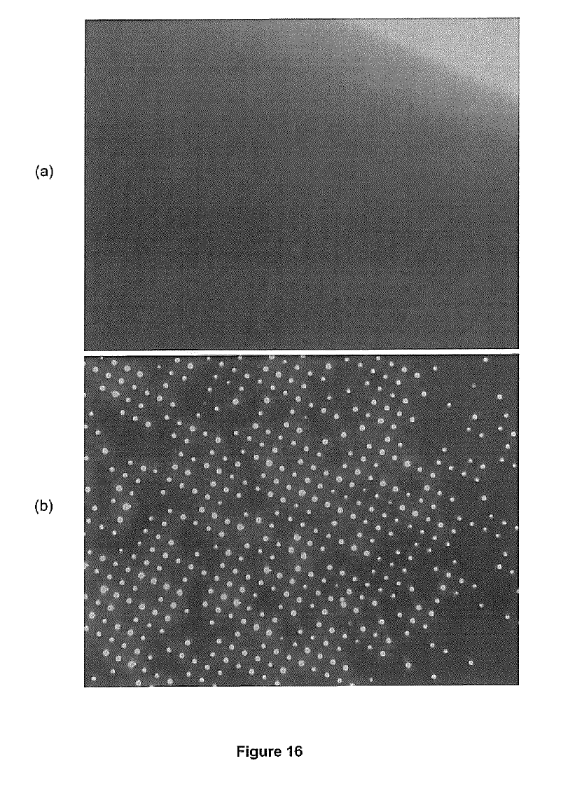

Similarly, FIG. 16 provides images of an array of 4 micron diameter wells. In FIG. 16(a) the empty array is shown. FIG. 16(b) shows the array after capture of 2 micron beads, where the majority of the wells have captured a single 2 micron bead.

In another embodiment, particles are sorted by dispensing liquid into an array of wells formed on a liquid sampling chip, where the liquid sampling chip is housed in a chip holder according to the aforementioned embodiment of the invention described with reference to FIG. 8. The use of a chip holder with external access through an aperture (preferably a single-well aperture) and an internal reservoir is especially useful in maintaining a humid environment for preserving a stable meniscus. Furthermore, the reservoir is highly advantageous in applications where it is important to continuously maintain a hydrated environment for particles sorted into wells, such as cells and protein crystals.

In another embodiment, such a liquid sampling chip residing in a covered chip holder is employed for the selective deposition of micro- or nano-crystals into wells. This is achieved, as discussed above, by selecting a well diameter that is sufficiently large to contain a single crystal. For example, the diameter may be selected to be approximately equal to the largest known or expected crystal size, or slightly larger than the average crystal size. This embodiment is particular well suited for the analysis of single crystals by x-ray crystallography and photocrystallography.

X-Ray crystallography is among the most powerful techniques to investigate structures at atomic level. Where the limitations associated with the penetration of probes require that nano-crystals be used for the analysis, an embodiment is desirable to mediate the production of such crystals on nano-scale dimensions. Moreover, in applications where making a molecular movie of the real-time structural changes in the molecule is desired, thousands of molecular ‘frames’ must be captured. An ideal sampling device for this application must also allow for an efficient sampling of thousands of crystals and/or nano-crystals to capture all the ‘frames’ of the molecular movie in a short period of time.

Unfortunately, existing methods of providing crystals for photocrystallography suffer from numerous drawbacks. Individually mounting 10,000 crystals is onerous and impractical due to the time and effort involved. Alternatively, the aerosol jet method requires a large number of crystals—most light flashes with not be hitting a falling crystal in the aerosol jet—and days of beam time to complete all reflections. Accordingly, there is a need for high throughput rapid isolation of single crystals for photocrystallographic diffraction.

In addition, conventional high-throughput crystallography efforts, especially those focused on the membrane proteins, will also greatly benefit from such a platform. While the majority of discovered drug targets are membrane-bound proteins, only a handful of membrane proteins have been shown to produce diffractable crystals. Despite the fact that most membrane proteins have proven difficult to crystallize, many have been shown to form micro-crystals, too small to be diffracted using conventional diffraction studies. In this regard, new effort has been directed at developing new ultra-bright synchrotron light sources to facilitate structural studies on nano- or micro-crystals, which are more readily obtainable in the case of membrane-bound proteins.

Recently, x-ray free electron lasers have been shown to hold great promise to obtain high resolution structural snap shots of proteins on the femtosecond time scale, revealing key ultra-fast motions underlying protein dynamics. To have utility in high throughput photocrystallography, a sampling device onto which the 2D crystals (or thin crystal films) are mounted (or grown) should possess very thin (on the nm scale) membrane of defined lattice structure to permit transmission of signal, and facilitate subsequent analysis of the diffraction data. Alternatively, a grazing incidence scattering, can be employed to record the diffraction data in the case of 3D micro-crystals, as described previously. A preferred sampling device for photocrystallography is therefore a liquid sampling chip with an array of selectively wettable microwells, allowing for thousands of crystals to be precisely aligned, for sample translation during the data acquisition.

Protein crystals must be kept hydrated during the course of X-Ray analysis. Therefore, X-Ray crystallography of protein crystals is often preformed on frozen crystals. However, freezing often results in crystal fracture. Therefore, prior to freezing, crystals are soaked in a cryoprotectant solution. The soaking in turn may often results in crystal fracture as in and the conditions for cryoprotection are often optimized by trial and error. Those skilled in the art will appreciate the significance of this invention for high throughput room temperature crystallography. Therefore, an embodiment provides a sampling device for efficient sorting of crystals into well array, keeping them hydrated during the course of diffraction.

Therefore, an embodiment of the invention provides a sampling device for sorting and housing micro- and nanocrystals in an array of wells. For the production of micro, the sampling device comprises a microchip possessing an array of microwells having a depth and lateral dimension suitable for the capture and/or growth of single crystals. As described above, an array of microwells may be selectively wettable relative to the upper surface by increasing the hydrophilicity of the upper surface relative to that of the well side wall.

In a preferred method for producing crystals, a droplet of mother liquor is translated (by a droplet-forming dispensing device or by brooming, wiping or other methods of translating a liquid such as spin coating or shaking) along the upper surface of the well array and contacted with a plurality of wells, causing the wells to be selectively filled with the mother liquor for controlled and isolated crystal growth. To fill the well with liquid, the droplet is translated past the distal wall of the well, where a liquid film ruptures and liquid from the droplet is consequently captured by the well.

In this embodiment, crystals to be analyzed by x-ray or electron beam can be grown in situ in the wells through dynamic wetting using the crystal growth solution (protein and precipitant), and excess reservoir solution of the precipitant to drive the crystallization in the closed chamber discussed above. For high throughput crystallography, a large number of crystalline particles must be positioned in prescribed positions in an array of known symmetry such that.

Where sorting of fragile crystalline particles into the well array by dynamic wetting proves difficult (for instance in the case of fragile two-dimensional or ultra thin plate like crystals, such crystals can be grown in situ in the well array. One of the most common methods of driving protein crystallization relies on vapor diffusion. In this method, a solution of purified protein is first mixed with a given amount of a precipitant material. This mixture is then incubated in an enclosure in the presence of a larger reservoir of precipitant of higher concentration. The enclosure provides an equilibrium condition, as water vapor leaves the protein/precipitant drop and enters the reservoir, the precipitant concentration gradually increases and this drives the crystallization.

In this embodiment, the well array can be wetted with protein/precipitant solution, and a reservoir drop of precipitant in the enclosure provides the equilibrium conditions required to drive the crystallization.

In another embodiment in which crystals have already been formed within a liquid, crystals may be sorted among wells according to the method described above. In yet another embodiment involving crystal sorting, the well array may also allow for a selective high throughput deposition (by size, shape sorting for e.g.) of the crystals conforming to pre-defined a dimensions by providing wells with various dimensions such that by sliding the chip against a droplet containing the crystals those conforming to a predefined dimensions and shape are sorted into the wells. After having obtained crystals within the wells of an array (by sorting and/or growth) the crystals may be incubated and hydrated within a chip holder as described above.

The wells for this application can be produced using a variety of photolithographic or electron beam lithography methods. In order to keep the x-ray scatter from the base to a minimum, the bottom wall of the well must be made very thin.

In this embodiment, wet chemical etching (such as but not limited to KOH) in combination with appropriate resist material for the etchant of choice, such as but not limited to SiN for KOH, is an alternative means of reducing the base thickness of the silicon wafer from the backside. A thin nitride layer (resistant to KOH etching) is deposited on both sides of the wafer. The nitride on the back side is first removed by RIE exposing the silicon. The wafer is then immersed in KOH such that silicon from the backside is etched. The front surface is then subjected to photolithography and etching. Subsequently, the nitride mask is removed also by RIE from the front surface. This process produces an embodiment in which a well is formed in a silicon substrate, where the thickness of the bottom wall of the well is dramatically reduced.

In a related embodiment of the invention, well structures with no bottom wall provide a means of eliminating the scatter from the base. Dynamic wetting (driven by contact line stability) allows for bottomless well structures to be fully wetted. In a non-limiting embodiment of room temperature x-ray crystallography of nano or micro crystals, bottomless well structures provide ideal platform as they offer virtually zero scatter background from the base.

The wells for this application can be produced using a variety of photolithographic or electron beam lithography methods. For submicron wells, electron beam lithography which is not limited in resolution by the diffraction limit of light can be used to obtain features down to 10 nm in size. This method uses a focused beam of electrons to write patterns on substrates. Electron beam sensitive resists are first spin coated on the substrate and then electron exposure modifies the resist allowing for downstream methods of etching and substrate modification.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1-50. (canceled)

51. A liquid sampling apparatus comprising:
a substrate having a well formed below a top surface thereof, wherein a relative hydrophilicity of said top surface and a side wall of said well is sufficient for dynamic wetting of said well, wherein a depth of said well is on a micron or nanometer scale.

52. The liquid sampling apparatus according to claim 51 where the aspect ratio of said well exceeds 100.

53. The liquid sampling apparatus according to claim 51 wherein a bottom surface of said well is hydrophillic.

54. The liquid sampling apparatus according to claim 51 where said relative hydrophilicity of said top surface and said side wall is associated with a relative surface roughness of said top surface and said side wall.

55. The liquid sampling apparatus according to claim 51 wherein said relative hydrophilicity of said top surface and said side wall is associated with a relative surface chemistry of said top surface and said side wall.

56. The liquid sampling apparatus according to claim 51 wherein said substrate comprises a top layer and a bottom layer, and wherein said well is defined in said top layer such that said bottom layer forms a bottom surface of said well.

57. The liquid sampling apparatus according to claim 56 wherein said top layer has a thickness on a nanometer scale.

58. The liquid sampling apparatus according to claim 57 wherein said top layer comprises silicon nitride, and wherein said bottom layer comprises silicon dioxide or fused silica.

59. The liquid sampling apparatus according to claim 51 wherein an average surface roughness of a bottom surface is approximately equal to an average depth of said well.

60. The liquid sampling apparatus according to claim 51 wherein a bottom surface of said well has a surface roughness approximately equal to or exceeding a surface roughness of said top surface.

61. The liquid sampling apparatus according to claim 51 wherein said well is filled with a liquid having a depth on a micron scale.

62. The liquid sampling apparatus according to claim 51 wherein said well is filled with a liquid having a depth on a nanometer scale.

63. The liquid sampling apparatus according to claim 51 wherein said substrate is selected from the group consisting of silicon, sapphire, quartz, glass, silica, fused silica, silicon dioxide, silicon oxide and silicon nitride.

64. The liquid sampling apparatus according to claim 51 further comprising one or more additional wells, wherein said wells are formed in an array.

65. The liquid sampling apparatus according to claim 64 further comprising:
a housing adapted to providing external access to one or more of said wells while maintaining a saturating environment for a remainder of said wells, said housing comprising:
a support for receiving said substrate;
a reservoir for maintaining a vapor pressure within said housing; and
a slidable cover, said slidable cover including an aperture for providing external access to one or more of said wells when said substrate is provided within said housing;
wherein a position of said aperture relative to said wells is adjustable, such that said aperture is positionable over one or more of said wells while a remainder of said wells and said reservoir remain substantially enclosed within said housing.

66. The liquid sampling apparatus according to claim 65 wherein said aperture is larger than a distal portion of a droplet dispensing device for dynamically wetting one or more of said wells.

67. A method of dispensing a liquid film into a well, the method comprising the steps of:
a) providing a liquid sampling apparatus comprising a well formed within a substrate, said substrate comprising a top surface, wherein a relative hydrophilicity of said top surface and side-wall of said well is sufficient for dynamic wetting of said well, wherein a depth of said well is on a micron or nanometer scale;
b) contacting a liquid droplet with said well and dynamically wetting the well; and
c) translating the droplet relative to the well, such that the liquid film is retained in the well, wherein the liquid film has a film thickness on a micron to nanometer scale.

68. The method according to claim 67 wherein said liquid sampling apparatus includes two or more of said wells, and wherein step a) includes:
providing said substrate within a housing adapted to providing external access to one or more of the wells while maintaining a saturating environment for a remainder of said wells, the housing comprising a support for receiving the substrate, a reservoir for maintaining a vapor pressure within the housing, and a slidable cover, wherein the slidable cover includes an aperture for providing external access to one or more of the wells when the substrate is provided within the housing, and wherein a position of the aperture relative to the wells is adjustable, such that the aperture is positionable over one or more of the wells while a remainder of the wells and the reservoir remain substantially enclosed within the housing;
filling the reservoir with a liquid suitable for maintaining a saturating environment within the housing; and
positioning the aperture over the well into which the liquid is to be dispensed.

69. The method according to claim 68 further comprising:
positioning the aperture over an additional well; and
dynamically dispensing the liquid into the additional well.

70. The method according to claim 68 wherein the reservoir includes a liquid that is substantially equivalent to a liquid contained in one or more of the wells.

71. A method of fabricating a liquid sampling apparatus, said method comprising the steps of:
providing a substrate comprising a top surface with a surface roughness on a micron scale;
applying a layer of photoresist onto the top surface;
lithographically exposing a region of the top surface, the region defining an aperture of a well;
fabricating the well by reactive ion etching; and
removing remaining photoresist from the top surface.

72. The method according to claim 71 further comprising the step of reducing a thickness of the substrate beneath a location corresponding to the well.

73. The method according to claim 72 wherein the substrate comprises silicon, and wherein the step of reducing the thickness of the substrate comprises the steps of:
forming a top layer of silicon nitride on a top of the substrate and a bottom layer of silicon nitride on a bottom layer of the substrate;
removing a portion of said bottom layer by reactive ion etching, and defining an aperture; and
contacting the substrate with KOH and etching the substrate through the aperture, wherein the etching is performed to obtain a suitable substrate thickness.
